(19) United States
(12) Patent Application Publication
(10) Pub. No.: US 2026/0076261 A1
(43) Pub. Date: Mar. 12, 2026

(54) SEMICONDUCTOR STRUCTURE AND FABRICATION METHOD THEREOF AND SEMICONDUCTOR DEVICE

(71) Applicant: Yangtze Memory Technologies Holding Co., Ltd., Wuhan (CN)

(72) Inventors: Huijie Zhu, Wuhan (CN); Peng Chen, Wuhan (CN); Ping Mo, Wuhan (CN); Xinru Zeng, Wuhan (CN); Zhong Lv, Wuhan (CN)

(21) Appl. No.: 19/236,785

(22) Filed: Jun. 12, 2025

(30) Foreign Application Priority Data
Sep. 10, 2024 (CN) 202411266802.7

(51) Int. Cl. H01L 25/16; H01L 25/00; H10B 80/00

(52) U.S. Cl. CPC H10W 90/00; H10B 80/00

(57) ABSTRACT

Examples of the present disclosure provide a semiconductor structure and a fabrication method thereof and a semiconductor device, and relates to the field of semiconductor technology. The semiconductor structure includes a interposer layer and a bonding block that are stacked together. The bonding block includes a connection portion and a plurality of stacks, and the connection portion connects any two adjacent stacks. Any one of the stacks is bonded with the interposer layer. In the examples, the connection portion connects any two adjacent stacks, such that the plurality of stacks in the bonding block can be jointly bonded with the interposer layer, and there is no need to bond the plurality of stacks with the interposer layer separately, thereby improving production efficiency and unit per hour of the semiconductor structure and also improving convenience of bonding between the stacks and interposer layer, which facilitates miniaturization of the stacks.

### CROSS-REFERENCE TO RELATED APPLICATIONS

The present application claims the benefit of priority to Chinese Application No. 202411266802.7, filed on Sep. 10, 2024, which is hereby incorporated by reference in its entirety.

### TECHNICAL FIELD

The present disclosure relates to the field of semiconductor technology, and particularly, to semiconductor structures and fabrication methods thereof and semiconductor devices.

### BACKGROUND

A semiconductor structure may comprise a stack and an interposer layer that are bonded together. There may be a plurality of stacks. During the production process, it is usually necessary to bond the plurality of stacks with the interposer layer separately, which affects the production efficiency of the semiconductor structure.

### SUMMARY

Examples of the present disclosure provide a semiconductor structure and a fabrication method thereof and a semiconductor device.

The examples of the present disclosure adopt the following technical solutions:

In an aspect, a semiconductor structure is provided. The semiconductor structure comprises a interposer layer and a bonding block. The bonding block and the interposer layer are stacked together. The bonding block comprises a connection portion and a plurality of stacks. The connection portion connects any two adjacent ones of the stacks. Any one of the stacks is bonded with the interposer layer.

In some examples, the semiconductor structure comprises a plurality of bonding blocks. The plurality of bonding blocks are stacked together, and any two adjacent ones of the plurality of bonding blocks are bonded with each other.

In some examples, in any two adjacent ones of the bonding blocks, a plurality of stacks in one bonding block and a plurality of stacks in the other bonding block are bonded in a one-to-one correspondence.

In some examples, the connection portion comprises a connection medium and metal routings embedded in the connection medium.

In some examples, the stack comprises a logic chip and a memory chip that are stacked together, and the memory chip is bonded with the logic chip.

In some examples, the stack comprises a plurality of memory chips that are stacked together on a side of the logic chip. Any two adjacent ones of the memory chips are bonded with each other.

In some examples, the memory chip and the logic chip are bonded by at least one of adhesive bonding, anodic bonding, direct wafer bonding, metal bonding and hybrid bonding.

In some examples, the bonding block and the interposer layer are bonded by at least one of adhesive bonding, anodic bonding, direct wafer bonding, metal bonding and hybrid bonding.

In some examples, the plurality of stacks are arranged along at least one of a first direction and a second direction. The first direction intersects the second direction, and a plane where the first direction and the second direction are located is parallel to the interposer layer.

In another aspect, a fabrication method of a semiconductor structure is provided. The fabrication method of the semiconductor structure comprises: forming a bonding block that comprises a connection portion and a plurality of stacks, wherein the connection portion connects any two adjacent ones of the stacks; and bonding any one of the stacks with a interposer layer.

In some examples, forming the bonding block comprises: bonding a memory wafer and a logic wafer to form a stack wafer comprising m stacks that are connected together; and cutting the stack wafer to form the bonding block comprising n stacks that are connected together, wherein m is greater than or equal to n, and both m and n are positive integers greater than 1.

In some examples, m is greater than n. After bonding the memory wafer and the logic wafer, the fabrication method comprises: cutting the stack wafer to form a first stack and a second stack.

In some examples, before bonding the memory wafer and the logic wafer, the fabrication method further comprises: forming the memory wafer on a side of a first substrate, wherein the memory wafer comprises a plurality of memory chips, and any two adjacent ones of the plurality of memory chips are connected with each other; and forming the logic wafer on a side of a second substrate, wherein the logic wafer comprises a plurality of logic chips, and any two adjacent ones of the plurality of logic chips are connected with each other. Bonding the memory wafer and the logic wafer comprises: bonding the plurality of memory chips and the plurality of logic chips in a one-to-one correspondence.

In yet another aspect, a semiconductor device is provided. The semiconductor device comprises a circuit board and a semiconductor structure as described above, wherein the interposer layer of the semiconductor structure is coupled with the circuit board.

In some examples, the semiconductor device further comprises a die that is bonded with the interposer layer.

In some examples, the die comprises a graphics processing unit.

In some examples, the semiconductor structure of the semiconductor device comprises a plurality of bonding blocks, the plurality of bonding blocks are stacked together, and any two adjacent ones of the plurality of bonding blocks are bonded with each other.

In some examples, in any two adjacent ones of the bonding blocks, a plurality of stacks in one bonding block and a plurality of stacks in the other bonding block are bonded in a one-to-one correspondence.

In some examples, the connection portion comprises a connection medium and metal routings embedded in the connection medium.

In some examples, the stack comprises a logic chip and a memory chip that are stacked together, and the memory chip is bonded with the logic chip.

### BRIEF DESCRIPTION OF THE DRAWINGS

In order to illustrate the technical solutions in the present disclosure more clearly, the drawings to be used in some examples of the present disclosure will be briefly introduced below. Apparently, the drawings in the following description are only drawings of some examples of the present disclosure. Those of ordinary skills in the art may also obtain other drawings according to these drawings. In addition, the drawings in the following description may be regarded as schematic diagrams, instead of limitations to actual size of product, actual flow of method, actual timing of signal, etc. involved in the examples of the present disclosure.

FIG. 1 is a schematic structural diagram of a semiconductor device provided by some examples of the present disclosure;

FIG. 2 is a schematic structural diagram of a stack provided by some examples of the present disclosure;

FIG. 3 is a schematic structural diagram of a semiconductor device provided by some other examples of the present disclosure;

FIG. 4 is a schematic diagram of arrangement of stacks provided by some examples of the present disclosure;

FIG. 5 is a schematic diagram of arrangement of stacks provided by some other examples of the present disclosure;

FIG. 6 is a schematic diagram of arrangement of stacks provided by some other examples of the present disclosure;

FIG. 7 is a schematic diagram of arrangement of stacks provided by some other examples of the present disclosure;

FIG. 8 is a schematic diagram of arrangement of stacks provided by some other examples of the present disclosure;

FIG. 9 is a schematic structural diagram of a semiconductor device provided by some other examples of the present disclosure;

FIG. 10 is a schematic structural diagram of a semiconductor device provided by some other examples of the present disclosure;

FIG. 11 is a flow diagram of a fabrication method of a semiconductor structure provided by some examples of the present disclosure;

FIG. 12 is a flow diagram of a fabrication method of a semiconductor structure provided by some other examples of the present disclosure;

FIG. 13 is a schematic diagram of arrangement of a bonding block, a first stack and a second stack on a substrate provided by some examples of the present disclosure;

FIG. 14 is a schematic diagram of arrangement of a first stack on a substrate provided by some examples of the present disclosure; and

FIG. 15 is a schematic diagram of arrangement of a second stack on a substrate provided by some examples of the present disclosure.

### DETAILED DESCRIPTION

The technical solutions in some examples of the present disclosure will be described below clearly and completely in conjunction with the drawings. Apparently, the examples described are only part of, but not all of, the examples of the present disclosure. All other examples obtained by those of ordinary skills in the art based on the examples provided by the present disclosure shall fall within the scope of protection of the present disclosure.

Unless otherwise specified in the context, throughout the specification and the claims, the term “comprise” is interpreted as an open and inclusive meaning, i.e., “including, but not limited to”. In the description of the specification, the terms “one example”, “some examples”, or “in an example” etc. are intended to indicate that particular features, structures, materials, or characteristics related to the example or examples are included in at least one example of the present disclosure. The schematic representation of the above terms may not necessarily refer to the same example. Furthermore, these particular features, structures, materials, or characteristics may be included in any one or more examples in any suitable manner.

In the following, the terms “first” and “second” are only for the purpose of description, and cannot be construed as indicating or implying relative importance or implicitly indicating the number of indicated technical features. Thus, features defined by “first” and “second” may explicitly or implicitly comprise one or more of such features. In the description of the examples of the present disclosure, “a plurality of”means two or more, unless otherwise stated.

In the description of some examples, the expressions “coupled” and “connected” and derivatives thereof may be used. For example, the term “connected” may be used in the description of some examples to indicate that two or more components have a direct physical contact or electrical contact with each other. For another example, the term “coupled” may be used in the description of some examples to indicate that two or more components have a direct physical contact or electrical contact. However, the term “coupled” may also mean that two or more components have no direct contact with each other, but still cooperate or interact with each other. The examples disclosed herein are not necessarily limited to the content herein.

Example implementations are described herein with reference to cross-sectional views and/or plan views used as idealized example drawings. In the drawings, thicknesses of layers and regions are exaggerated for clarity. Thus, changes in shapes relative to the drawings caused by, for example, manufacturing technology and/or tolerance, may be contemplated. Therefore, the example implementations should not be interpreted as being limited to the shapes of regions shown herein, but rather comprising shape deviations caused by, for example, manufacturing. For example, an etching region shown as a rectangle will typically have a curved feature. Therefore, the regions shown in the drawings are essentially schematic, and their shapes are neither intended to show actual shapes of regions of the device, nor intended to limit the scope of the example implementations.

As used herein, the term “substrate” refers to a material onto which subsequent material layers may be added. The substrate itself can be patterned. Materials added onto the substrate can be patterned or can remain unpatterned. Furthermore, the substrate may comprise a variety of semiconductor materials, such as silicon, germanium, gallium arsenide, indium phosphide, etc. Alternatively, the substrate can be made from an electrically non-conductive material, such as glass, plastic, or sapphire wafer, etc.

Some examples of the present disclosure further provide an electronic apparatus. In an example, the electronic apparatus may be a mobile phone, a desktop computer, a laptop computer, a tablet, a vehicle computer, a gaming console, a printer, a positioning apparatus, a wearable electronic apparatus (e.g., a smart watch, a smart bracelet, smart glasses, etc.), a smart sensor, a virtual reality (VR) apparatus, an augmented reality (AR) apparatus, or any other electronic apparatuses.

The electronic apparatus may comprise a semiconductor device 200 that can achieve storing, computing, processing and other functions. The examples of the present disclosure do not have further limitations on the specific form of the electronic apparatus. The structure of the semiconductor device 200 is illustrated below.

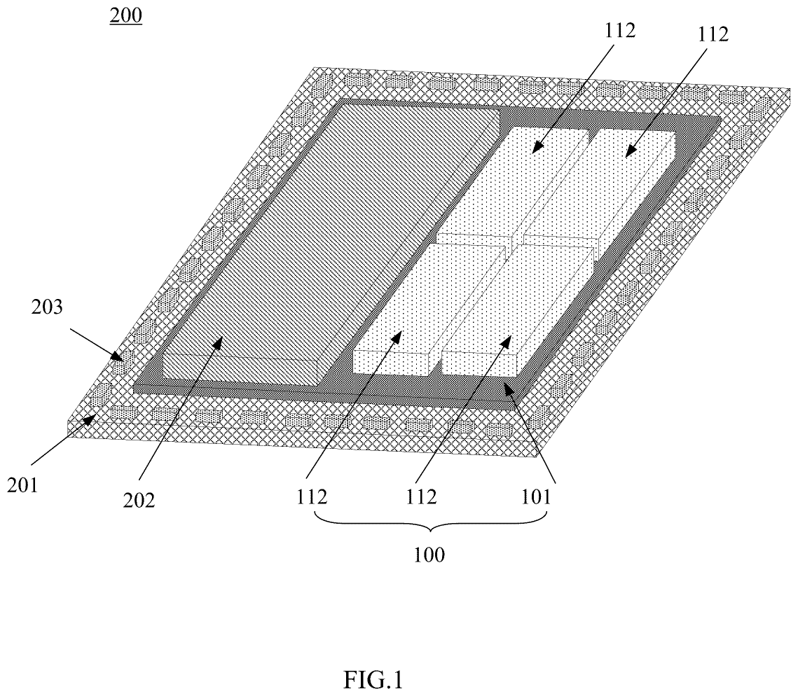

FIG. 1 is a schematic structural diagram of a semiconductor device provided by some examples of the present disclosure. In some examples, as shown in FIG. 1, the semiconductor device 200 may comprise a circuit board 201 and a semiconductor structure 100.

The circuit board 201 may be a printed circuit board (PCB), a flexible printed circuit (FPC) or a rigid-flex printed circuit board (RFPCB). The semiconductor structure 100 is coupled with the circuit board 201. In an example, the semiconductor structure 100 may comprise a three dimensional integrated circuit (3D IC).

In some examples, as shown in FIG. 1, the semiconductor structure 100 may comprise a interposer layer 101 that is coupled with the circuit board 201. In an example, the interposer layer 101 may be a Si interposer.

As shown in FIG. 1, the semiconductor structure 100 may further comprise a stack 112 that is bonded with the interposer layer 101. It may be understood that the stack 112 can be coupled with the circuit board 201 through the interposer layer 101.

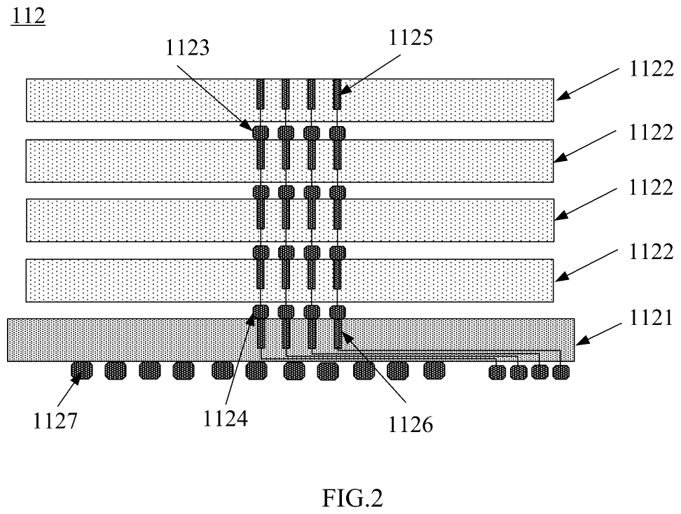

FIG. 2 is a schematic structural diagram of a stack provided by some examples of the present disclosure. As shown in FIG. 2, the stack 112 may comprise a plurality of chips that are stacked together. In some examples, the stack 112 may comprise a logic chip 1121 and a memory chip 1122 that are stacked together, and the memory chip 1122 is bonded with the logic chip 1121.

It may be understood that the memory chip 1122 can achieve a storage function. In an example, the memory chip 1122 may be a dynamic random access memory (DRAM), a random access memory (RAM), a static random-access memory (SRAM), a read only memory (ROM), etc. The memory chip 1122 is bonded with the logic chip 1121, such that the logic chip 1121 can control the memory chip 1122 to read, write and store data.

In some examples, the memory chip 1122 is bonded with the logic chip 1121, such that a high bandwidth memory (HBM) stack can be formed, i.e., the stack 112 is an HBM stack. In some other examples, other memory stacks may be also formed after the memory chip 1122 is bonded with the logic chip 1121. It may be understood that the stack 112 may comprise other chips than the memory chip 1122 and the logic chip 1121.

The HBM stack being formed by bonding the memory chip 1122 and the logic chip 1121 (i.e., the stack 112 is the HBM stack) is taken as an example for continuous illustration in the examples of the present disclosure.

In some examples, the memory chip 1122 and the logic chip 1121 are bonded by at least one of adhesive bonding, anodic bonding, direct wafer bonding, metal bonding and hybrid bonding (HB).

As such, the flexibility during the bonding of the memory chip 1122 and the logic chip 1121 can be improved. It may be understood that the memory chip 1122 and the logic chip 1121 may be also bonded by other manners than the above-mentioned manners.

In some examples, as shown in FIG. 2, the stack 112 comprises a plurality of memory chips 1122 stacked together on a side of the logic chip 1121. Any two adjacent ones of the memory chips 1122 are bonded with each other.

The storage capacity of the stack 112 can be increased by disposing the plurality of memory chips 1122. In an example, any two adjacent ones of the memory chips 1122 may be bonded with each other by at least one of adhesive bonding, anodic bonding, direct wafer bonding, metal bonding and hybrid bonding to improve the flexibility during the bonding of any two adjacent ones of the memory chips 1122. It may be understood that any two adjacent ones of the memory chips 1122 may be also bonded by other manners than the above-mentioned manners.

In an example, as shown in FIG. 2, the stack 112 may comprise a first bonding metal 1123 and a second bonding metal 1124. The first bonding metal 1123 is located between two adjacent memory chips 1122, and the two adjacent memory chips 1122 are bonded through the first bonding metal 1123. The second bonding metal 1124 is located between the memory chip 1122 and the logic chip 1121 that are bonded with each other through the second bonding metal 1124.

As shown in FIG. 2, a first conductive via 1125 may be provided in the memory chip 1122, a second conductive via 1126 may be provided in the logic chip 1121, and the first conductive via 1125 and the second conductive via 1126 may be through silicon vias (TSVs). The number of the first conductive via 1125 and the number of the second conductive via 1126 may be the same or different. The plurality of memory chips 1122 may be coupled through the first conductive via 1125, and the memory chip 1122 and the logic chip 1121 may be coupled through the second conductive via 1126.

As shown in FIG. 2, the stack 112 may further comprise pins 1127 that are on a side of the logic chip 1121 away from the memory chip 1122. The pins 1127 may be metal ball grid array (BGA). The pins 1127 are used to couple the memory chip 1122 and the logic chip 1121 with other components (e.g., the interposer layer 101).

It may be understood that the stack 112 also may be other structures than the above-mentioned structure. The examples of the present disclosure do not have further limitations on the structure of the stack 112.

With reference to FIG. 1 again, in some examples, the semiconductor device 200 may further comprise a die 202 that is bonded with the interposer layer 101.

It may be understood that the die 202 and the stack 112 may be coupled with the interposer layer 101 separately, such that the die 202 can be coupled with the stack 112 through the interposer layer 101. The die 202 can achieve processing, computing or other functions, and can read data from the stack 112 or write data to the stack 112, such that the semiconductor device 200 can achieve processing, computing or other functions.

There may be one die 202 or multiple dies 202. When there are multiple dies 202, the multiple dies 202 may be spaced apart. The types of the multiple dies 202 may be the same or different.

In some example, the die 202 may comprise a graphics processing unit. As such, the semiconductor device 200 can achieve a graphics processing function. In this case, the semiconductor device 200 may be a graphics processing unit (GPU).

In some other examples, the die 202 may be other processing units than the graphics processing unit, e.g., a central processing unit (CPU).

With continued reference to FIG. 1, the semiconductor device 200 may further comprise other elements 203 that may be capacitors, resistors, or the like. The other elements 203 may be coupled with the circuit board 201. The examples of the present disclosure do not have further limitations on the types, number and locations of the other elements 203.

In an example, the semiconductor device 200 may further comprise a package structure to package the die 202 and the semiconductor structure 100.

In some examples, as shown in FIG. 1, there are a plurality of stacks 112 to increase the storage capacity of the semiconductor device 100 and improve the performance of the semiconductor device 200. In an example, the plurality of stacks 112 may be spaced apart.

The stack 112 and the interposer layer 101 are typically bonded by thermal chip bonding (TCB) that may include a non-conducting film (NCF) process and a molded underfill (MUF) process.

It may be understood that bonding the stack 112 and the interposer layer 101 is a complex process. When there are a plurality of stacks 112, the plurality of stacks 112 need to be bonded with the interposer layer 101 separately, which affects the production efficiency of the semiconductor structure 100, results in a low unit per hour (UPH) of the semiconductor structure 100 and increases the production cost.

Moreover, when the stack 112 is small in size, bonding the stack 112 and the interposer layer 101 will be more difficult, further affecting the production efficiency of the semiconductor structure 100.

In some implementations, wafer-to-wafer bonding may be used to bond the stack 112 and the interposer layer 101. In an example, a stack wafer 113 comprising the plurality of stacks 112 may be bonded with the interposer layer 101. However, the wafer-to-wafer bonding has a low yield, thereby affecting the yield of the semiconductor structure 100.

With the demands of the electronic apparatus on faster read/write speeds and larger storage capacity, etc. of the semiconductor structure 100, the utilization of internal space and high integration of the semiconductor structure 100 are facing more and more severe challenges. For the 3D IC, the problems in the unit per hour (UPH) of the process, the yield and the space utilization rate, etc. are major challenges that restrict the development of highly integrated package. For a thinner and higher process stack in the future, the above problems will become more severe.

On this basis, examples of the present disclosure provide a semiconductor structure 100 which can implement efficient mounting of 3D IC interconnections and achieve high-efficiency package die bonding.

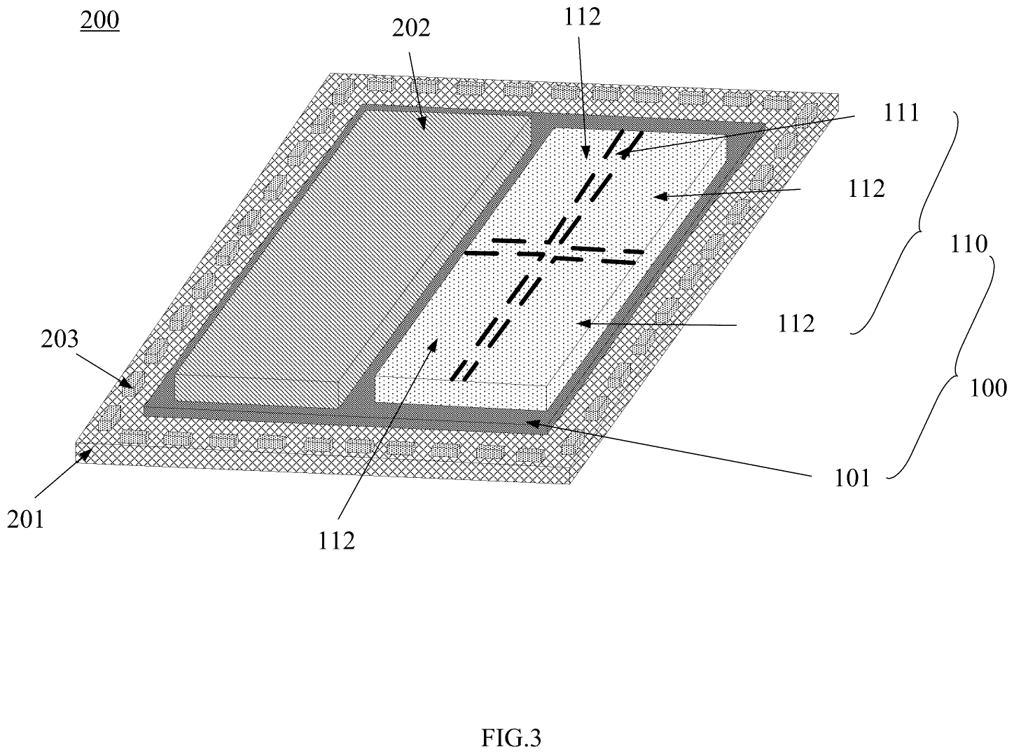

FIG. 3 is a schematic structural diagram of a semiconductor device provided by some other examples of the present disclosure. In some examples, as shown in FIG. 3, the semiconductor structure 100 comprises a bonding block 110, and the bonding block 110 and a interposer layer 101 are stacked together. The bonding block 110 comprises a connection portion 111 and a plurality of stacks 112. The connection portion 111 connects any two adjacent ones of the stacks 112. Any one of the stacks 112 is bonded with the interposer layer 101.

It may be understood that the plurality of stacks 112 are disposed along a direction parallel to the interposer layer 101. Any one of the stacks 112 is bonded with the interposer layer 101, that is, the plurality of stacks 112 in the bonding block 110 are all bonded with the interposer layer 101.

In the examples of the present disclosure, the connection portion 111 is provided to connect any two adjacent ones of the stacks 112, such that the plurality of stacks 112 in the bonding block 110 as a whole can be jointly bonded with the interposer layer 101, and there is no need to bond the plurality of stacks 112 with the interposer layer 101 separately. The process of bonding the plurality of stacks 112 with the interposer layer 101 is simplified, the production efficiency of the semiconductor structure 100 is improved, and the unit per hour (UPH) of the semiconductor structure 100 can be increased.

It may be understood that the unit per hour (UPH) of the semiconductor structure 100 can be multiplied according to the number of the stacks 112 in the bonding block 110, which effectively solves the bottleneck in the UPH of back-end-of-line packaging and is conducive to reducing the production cost of the semiconductor structure 100.

Moreover, the size of the bonding block 110 is greater than that of the stack 112. Compared with the stacks 112 being bonded with the interposer layer 101 separately, the plurality of stacks 112 in the bonding block 110 as a whole are jointly bonded with the interposer layer 101, which may improve the convenience during the bonding of the stacks 112 and the interposer layer 101.

As such, the limitations of the size of the stack 112 on the UPH can be reduced, and the decrease in the size of the stack 112 will not have a significant impact on the UPH of the semiconductor structure 100 and is conducive to reducing the size of the stack 112 at the fabrication (FAB) end, such that a more flexible wafer design can be achieved during the fabrication of the stack 112.

That is, the connection portion 111 is provided to connect any two adjacent ones of the stacks 112, which can facilitate the miniaturization of the stack 112, increase the space utilization rate inside the semiconductor device 200, achieves more flexible packaging (PKG) design and more flexible space utilization, and is conducive to achieving high integration.

Furthermore, the decrease in the size of the stack 112 can reduce the number of defects in the stack 112, and is conducive to increasing the yield of the stack 112, thereby increasing the yield of the semiconductor structure 100. Moreover, the area utilization rate of the stack wafer 113 (which comprises the plurality of stacks 112) can be also increased.

In some examples, the bonding block 110 and the interposer layer 101 are bonded by at least one of adhesive bonding, anodic bonding, direct wafer bonding, metal bonding and hybrid bonding. As such, the flexibility during the bonding of the bonding block 110 and the interposer layer 101 can be improved. It may be understood that the bonding block 110 and the interposer layer 101 may be bonded by other manners than the above-mentioned manners.

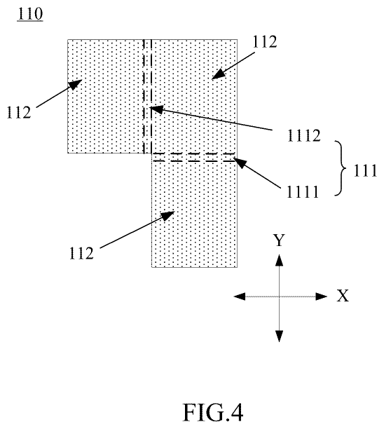

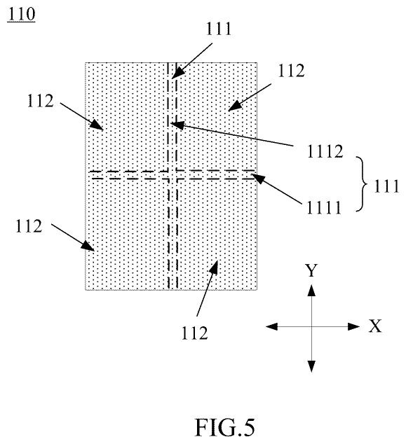

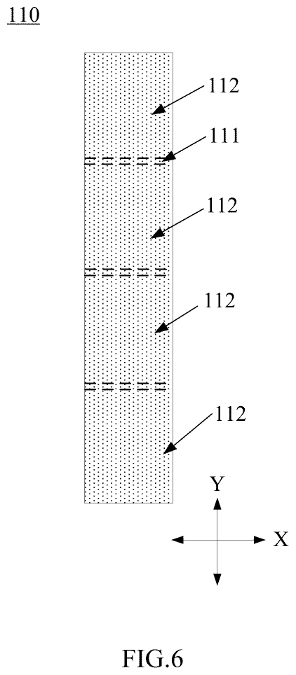

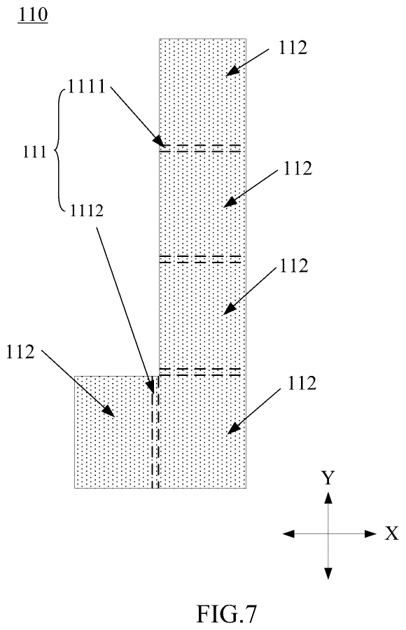

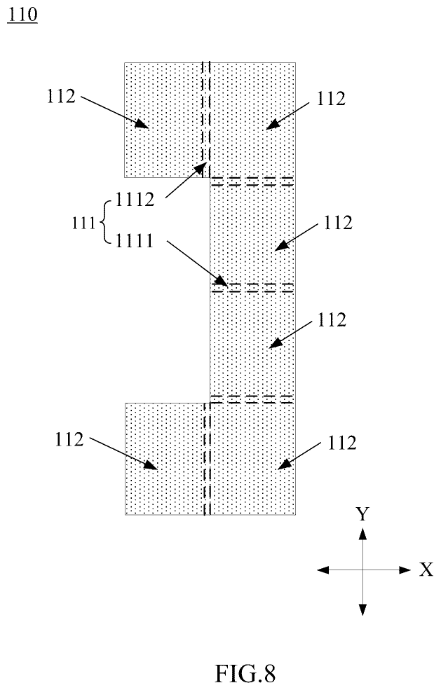

FIG. 4 is a schematic diagram of arrangement of stacks provided by some examples of the present disclosure. FIG. 5 is a schematic diagram of arrangement of stacks provided by some other examples of the present disclosure. FIG. 6 is a schematic diagram of arrangement of stacks provided by some other examples of the present disclosure. FIG. 7 is a schematic diagram of arrangement of stacks provided by some other examples of the present disclosure. FIG. 8 is a schematic diagram of arrangement of stacks provided by some other examples of the present disclosure.

In some examples, as shown in FIGS. 4, 5, 6, 7 and 8, the plurality of stacks 112 are arranged along at least one of a first direction X and a second direction Y. The first direction X intersects the second direction Y, and a plane where the first direction X and the second direction Y are located is parallel to the interposer layer 101.

It may be understood that the plurality of stacks 112 may be arranged only along the first direction X, or only along the second direction Y (referring to FIG. 6), or along both the first direction X and the second direction Y (referring to FIGS. 4, 5, 7 and 8).

When the plurality of stacks 112 are arranged along the first direction X and the second direction Y, the plurality of stacks 112 may be arranged in an array (referring to FIG. 5), or may be arranged along the first direction X and the second direction Y in another regular or irregular configuration (referring to FIGS. 4, 7 and 8). It may be understood that the examples of the present disclosure do not have further limitations on the arrangement configuration of the plurality of stacks 112 in the bonding block 110.

In an example, as shown in FIGS. 7 and 8, the connection portion 111 may comprise a first connection sub-portion 1111 extending along the first direction X and a second connection sub-portion 1112 extending along the second direction Y.

The first connection sub-portion 1111 is located between and connects two adjacent stacks 112 along the second direction Y. The second connection sub-portion 1112 is located between and connects two adjacent stacks 112 along the first direction X.

The plurality of stacks 112 are arranged along at least one of the first direction X and the second direction Y, which can improve the arrangement flexibility of the plurality of stacks 112, meets different demands, increases the space utilization rate and facilitates high density integration.

In an example, the connection portion 111 may be a cutting lane between two stacks 112. Alternatively, the connection portion 111 may be other connection structures. In the examples of the present disclosure, the structure of the connection portion 111 is illustrated by taking the connection portion 111 as a cutting lane.

In some examples, the connection portion 111 may comprise a connection medium and metal routings embedded in a connection medium.

In an example, a memory connection portion may be included between two adjacent memory chips 1122 and comprises a first connection sub-medium and first metal sub-routings embedded in the first connection sub-medium. A logic connection portion may be included between two adjacent logic chips 1121 and comprises a second connection sub-medium and second metal sub-routings embedded in the second connection sub-medium.

A memory wafer and a logic wafer are bonded to form a stack wafer 113, and a cutting lane of the stack wafer 113 comprises the memory connection portion and the logic connection portion that are stacked together, and is located between any two adjacent ones of the stacks 112.

The bonding block 110 comprising the plurality of stacks 112 may be formed by cutting the stack wafer 113 along a set cutting lane. Among the plurality of stacks 112 of the bonding block 110, the cutting lane between two adjacent ones of the stacks 112 is retained to form the connection portion 111, such that the connection portion 111 can comprise a connection medium and metal routings embedded in the connection medium.

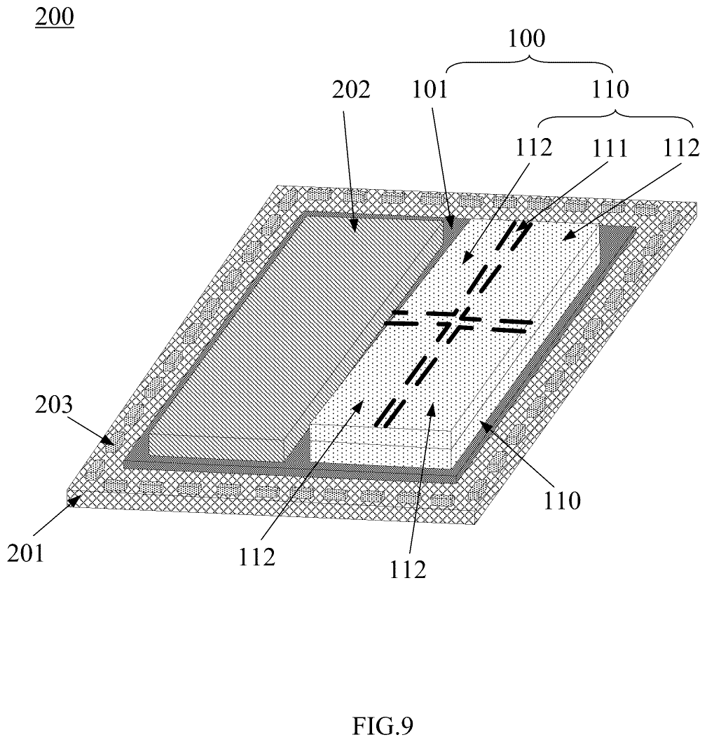

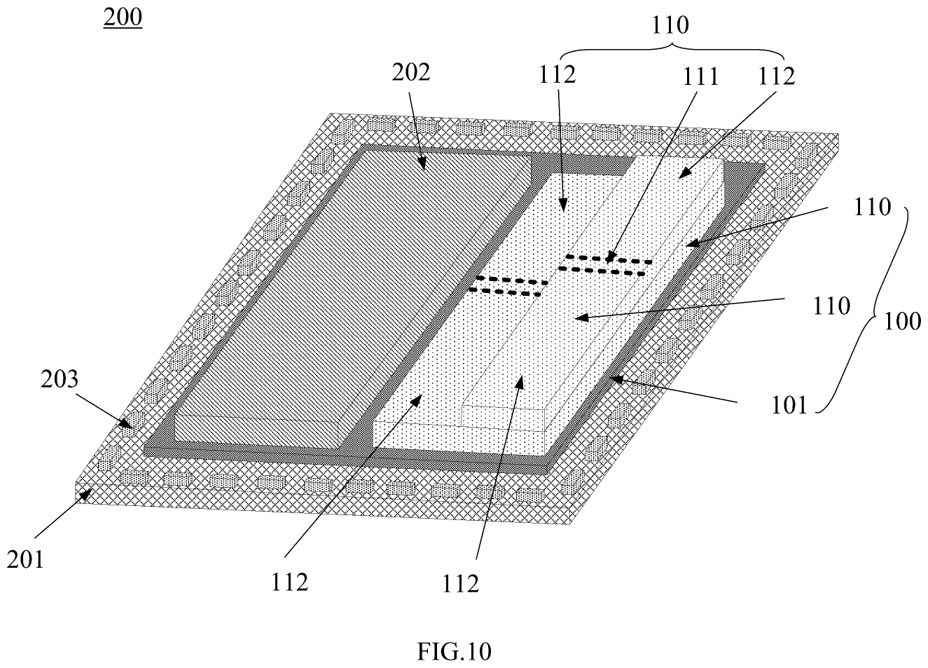

FIG. 9 is a schematic structural diagram of a semiconductor device provided by some other examples of the present disclosure. FIG. 10 is a schematic structural diagram of a semiconductor device provided by some other examples of the present disclosure.

In some examples, as shown in FIGS. 9 and 10, the semiconductor structure 100 comprises a plurality of bonding blocks 110. The plurality of bonding blocks 110 are stacked together, and any two adjacent ones of the plurality of bonding blocks 110 are bonded with each other.

It may be understood that among the plurality of bonding blocks 110, the numbers of the stacks 112 comprised in different bonding blocks 110 may be the same or different. The arrangements of the plurality of stacks 112 in different bonding blocks 110 may be the same or different.

In an example, as shown in FIG. 10, in any two adjacent ones of the bonding blocks 110, the number of the stacks 112 comprised in the bonding block 110 close to the interposer layer 101 may be greater than the number of the stacks 112 included in the bonding block 110 away from the interposer layer 101, such that the bonding block 110 close to the interposer layer 101 can support the bonding block 110 away from the interposer layer 101.

In an example, the type of bonding of the bonding block 110 and the interposer layer 101 may be referred to as B2W (block to wafer) bonding. The type of bonding of any two adjacent ones of the bonding blocks 110 is referred to as B2B (block to block) bonding.

The semiconductor structure 100 is provided to comprise a plurality of bonding blocks 110, which can increase the storage capacity of the semiconductor structure 100. The plurality of bonding blocks 110 are stacked together, and any two adjacent ones of the plurality of bonding blocks 110 are bonded with each other, such that the bonding efficiency between the plurality of bonding blocks 110 can be improved, the unit per hour (UPH) of the semiconductor structure 100 is increased, and the production cost is reduced.

In some examples, in any two adjacent ones of the bonding blocks 110, a plurality of stacks 112 in one bonding block 110 are bonded with a plurality of stacks 112 in the other bonding block 110 in a one-to-one correspondence. As such, the stacks 112 in different bonding blocks 110 may be bonded in a one-to-one correspondence.

A fabrication method of a semiconductor structure is illustrated below. In an example, the fabrication method of the semiconductor structure may be used to fabricate the semiconductor structure 100 as described above.

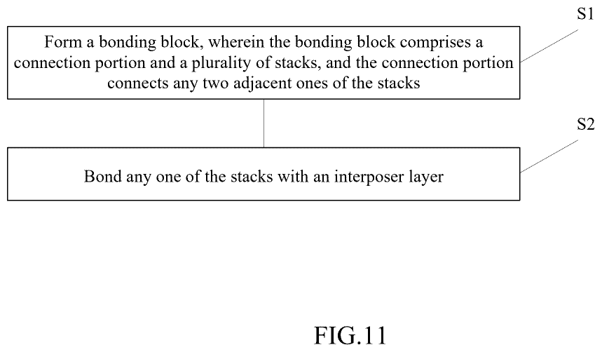

FIG. 11 is a flow diagram of a fabrication method of a semiconductor structure provided by some examples of the present disclosure. In some examples, as shown in FIG. 11, the fabrication method of the semiconductor structure comprises:
S1, forming a bonding block. The bonding block comprises a connection portion and a plurality of stacks, and the connection portion connects any two adjacent ones of the stacks;
S2, bonding any one of the stacks with an interposer layer.

It may be understood that the plurality of stacks 112 are disposed along a direction parallel to the interposer layer 101. Any one of the stacks 112 is bonded with the interposer layer 101, that is, the plurality of stacks 112 in the bonding block 110 are all bonded with the interposer layer 101.

The connection portion 111 is provided to connect any two adjacent ones of the stacks 112, such that the plurality of stacks 112 in the bonding block 110 as a whole can be jointly bonded with the interposer layer 101, and there is no need to bond the plurality of stacks 112 with the interposer layer 101 separately. Therefore, the process of bonding the plurality of stacks 112 with the interposer layer 101 is simplified, the production efficiency of the semiconductor structure 100 is improved, and the unit per hour (UPH) of the semiconductor structure 100 can be increased.

It may be understood that the unit per hour (UPH) of the semiconductor structure 100 can be multiplied according to the number of the stacks 112 in the bonding block 110, which effectively solves the bottleneck in the UPH of back-end-of-line packaging and is conducive to reducing the production cost of the semiconductor structure 100.

Moreover, the size of the bonding block 110 is greater than that of the stack 112. Compared with the stacks 112 being bonded with the interposer layer 101 separately, the plurality of stacks 112 in the bonding block 110 as a whole are jointly bonded with the interposer layer 101, which may improve the convenience during the bonding of the stacks 112 and the interposer layer 101.

As such, the limitations of the size of the stack 112 on the UPH can be reduced, and the decrease in the size of the stack 112 will not have a significant impact on the UPH of the semiconductor structure 100 and is conducive to reducing the size of the stack 112 at the fabrication (FAB) end, such that a more flexible wafer design can be achieved during the fabrication of the stack 112.

That is, the connection portion 111 is provided to connect any two adjacent ones of the stacks 112, which can facilitate the miniaturization of the stack 112, increase the space utilization rate inside the semiconductor device 200, achieves more flexible packaging (PKG) design and more flexible space utilization and is conducive to achieving high integration.

Furthermore, the decrease in the size of the stack 112 can reduce the number of defects in the stack 112, and is conducive to increasing the yield of the stack 112, thereby increasing the yield of the semiconductor structure 100.

In may be understood that the above examples of the present disclosure have illustrated the structures of the stack 112 and the connection portion 111 and the bonding manner between the bonding block 110 and the interposer layer 101, etc., which are no longer repeated herein.

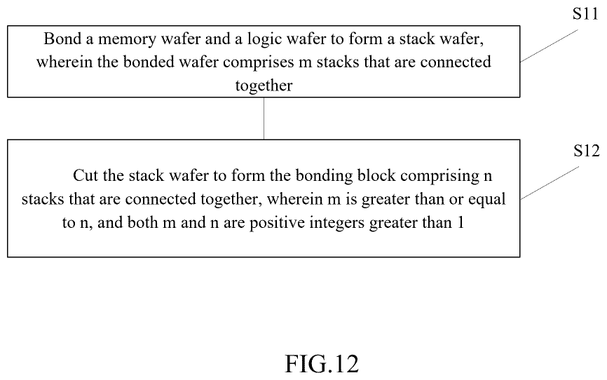

FIG. 12 is a flow diagram of a fabrication method of a semiconductor structure provided by some other examples of the present disclosure. In some examples, as shown in FIG. 12, forming the bonding block (i.e., S1) comprises:
S11, bonding a memory wafer and a logic wafer to form a stack wafer. The stack wafer comprises m stacks that are connected together.

In an example, the memory wafer may comprise m memory chips 1122, and the logic wafer may comprise m logic chips 1121, such that the stack wafer 113 can comprise m stacks 112 that are connected together after the memory wafer is bonded with the logic wafer to form the stack wafer 113.

In some examples, before bonding the memory wafer and the logic wafer (i.e., S11), the fabrication method further comprises:
S11a, forming the memory wafer on a side of a first substrate, wherein the memory wafer comprises a plurality of memory chips, and any two adjacent ones of the plurality of memory chips are connected with each other; and
S11b, forming the logic wafer on a side of a second substrate, wherein the logic wafer comprises a plurality of logic chips, and any two adjacent ones of the plurality of logic chips are connected with each other.

In the examples of the present disclosure, the substrate (e.g., the first substrate or the second substrate) may be a monocrystalline silicon (Si) substrate, a monocrystalline germanium (Ge) substrate, a silicon on insulator (SOI) substrate or a germanium on insulator (GOI) substrate, etc. Alternatively, the substrate may be a gallium arsenide (GaAs) substrate, an indium phosphide (InP) substrate or a silicon carbide (SiC) substrate, etc.

It may be understood that the plurality of memory chips 1122 are located on a side of the first substrate, and a memory connection portion is disposed between and connects any two adjacent ones of the memory chips 1122. The plurality of logic chips 1121 are located on a side of the second substrate, and a logic connection portion is disposed between and connects any two adjacent ones of the logic chips 1121.

Bonding the memory wafer and the logic wafer (i.e., S11) comprises: bonding the plurality of memory chips and the plurality of logic chips in a one-to-one correspondence.

In an example, the logic wafer and the memory wafer may be bonded by wafer-to-wafer bonding, such that the plurality of memory chips 1122 and the plurality of logic chips 1121 can be bonded in a one-to-one correspondence to form the stack wafer 113 comprising the plurality of stacks 112.

It may be understood that a cutting lane of the stack wafer 113 comprises the memory connection portion and the logic connection portion that are stacked together, and is located between any two adjacent ones of the stacks 112.

After bonding the memory wafer and the logic wafer (i.e., S11), the fabrication method of the semiconductor structure 100 further comprises:
S12, cutting the stack wafer to form the bonding block comprising n stacks that are connected together, wherein m is greater than or equal to n, and both m and n are positive integers greater than 1.

In an example, the stack wafer 113 comprising m stacks 112 that are connected together may be cut along a set cutting lane to form the bonding block 110 comprising n stacks 112 that are connected together. m is greater than or equal to n, and both m and n are positive integers greater than 1. It may be understood that the values of m and n may be the same or different. The examples of the present disclosure do not have further limitations on the values of m and n.

For example, when both m and n are equal to 2, the stack wafer 113 comprises two stacks 112 that are connected together. In this case, the stack wafer 113 may be cut to obtain one bonding block 110 that comprises two stacks 112 that are connected together.

When m is equal to 10 and n is equal to 2, the stack wafer 113 comprises ten stacks 112 that are connected together. In this case, the stack wafer 113 may be cut to obtain five bonding blocks 110 each comprising two stacks 112 that are connected together.

It may be understood that among the plurality of stacks 112 of the bonding block 110, a cutting lane between two adjacent ones of the stacks 112 is retained to form the connection portion 111. The connection portion 111 may comprise a connection medium and metal routings embedded in the connection medium.

By cutting the stack wafer 113, the bonding block 110 may comprise a plurality of stacks 112 that are connected together, which improves the convenience of fabricating the stacks 112.

In some examples, m is greater than n, such that the m stacks 112 of the stack wafer 113 can be cut into the bonding block 110, and a first stack 112a and a second stack 112b that are independent from the bonding block 110.

In an example, in the bonding block 110, the performance (e.g., speed, power consumption, stability, etc.) of the stack 112 is better than the performance of the first stack 112a and the second stack 112b. The performance of the first stack 112a is better than the performance of the second stack 112b.

In some examples, distinguishing the stack 112, the first stack 112a and the second stack 112 in the bonding block 110 according to their performance may be called as “binning”.

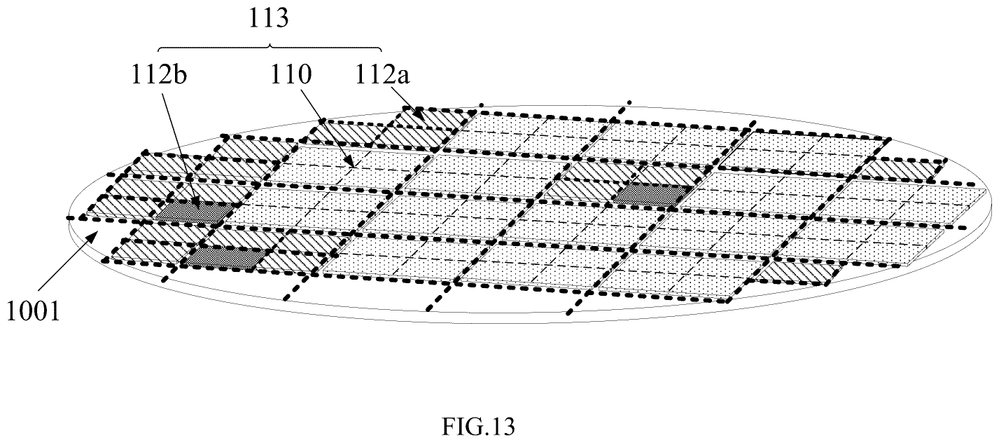

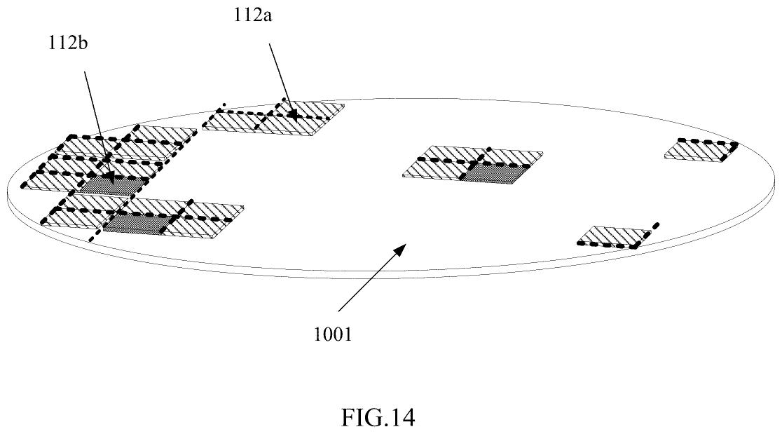

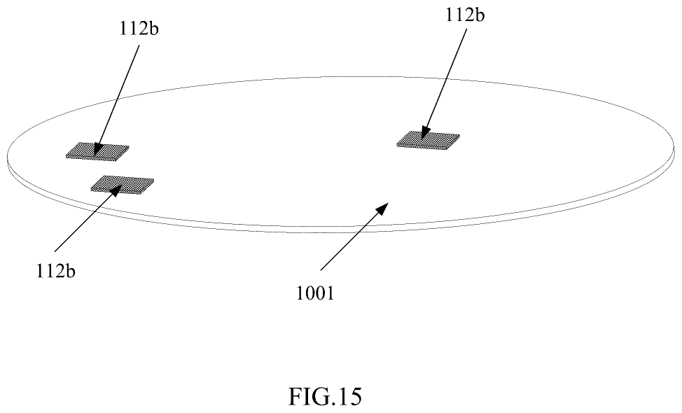

FIG. 13 is a schematic diagram of arrangement of a bonding block, a first stack and a second stack on a substrate provided by some examples of the present disclosure. FIG. 14 is a schematic diagram of arrangement of a first stack on a substrate provided by some examples of the present disclosure. FIG. 15 is a schematic diagram of arrangement of a second stack on a substrate provided by some examples of the present disclosure.

In some examples, after bonding the memory wafer and the logic wafer, the fabrication method comprises: cutting the stack wafer to form a first stack and a second stack.

In an example, as shown in FIG. 13, the stack wafer 113 is located on a side of a substrate 1001. In an example, the substrate 1001 may be one of the first substrate and the second substrate, or may be other substrates than the first substrate and the second substrate.

The stack wafer 113 is cut to form a plurality of bonding blocks 110, a plurality of first stacks 112a and a plurality of second stacks 112b at the same time. The numbers of the bonding blocks 110, the first stacks 112a and the second stacks 112b may be the same or different. The examples of the present disclosure do not have further limitations on the numbers of the bonding blocks 110, the first stacks 112a and the second stacks 112b cut from the stack wafer 113.

It may be understood that in the examples of the present disclosure, “at the same time” refers to in the same process step, and is not limited as the same time instant.

After cutting the stack wafer 113, the bonding block 110 and the substrate 1001 may be separated. As shown in FIG. 14, the first stack 112a and the second stack 112b are retained on the substrate 1001. The bonding block 110 is bonded with the interposer layer 101.

After the bonding block 110 and the substrate 1001 are separated, the first stack 112a and the substrate 1001 may be separated. As shown in FIG. 15, the second stack 112b is retained on the substrate 1001. The first stack 112a may be bonded with other components. In an example, the first stack 112a may be bonded with the interposer layer 101 of the semiconductor structure 100, or the first stack 112a may be also coupled with other semiconductor structures or semiconductor devices. The examples of the present disclosure do not have further limitations thereto.

After the first stack 112a and the substrate 1001 are separated, the second stack 112b and the substrate 1001 may be separated. The second stack 112b may be bonded with other components. In an example, the second stack 112b may be bonded with the interposer layer 101 of the semiconductor structure 100, or the second stack 112b may be also coupled with other semiconductor structures or semiconductor devices. The examples of the present disclosure do not have further limitations thereto.

In some other examples, the first stack 112a and the second stack 112b may be also first separated from the substrate 1001, and then the stack 112 is separated from the substrate 1001. The examples of the present disclosure do not have further limitations on the sequence of separation of the stack 112, the first stack 112a and the second stack 112b from the substrate 1001.

It may be understood that m is set to be greater than n, such that cutting the stack wafer 113 can form the bonding block 110, and the first stack 112a and the second stack 112 independent from the bonding block 110, and the area utilization rate of the stack wafer 113 is increased.

In summary, the examples of the present disclosure have at least the following advantageous effects:

In the examples of the present disclosure, the connection portion 111 is provided to connect any two adjacent ones of the stacks 112, such that the plurality of stacks 112 in the bonding block 110 as a whole can be jointly bonded with the interposer layer 101, and there is no need to bond the plurality of stacks 112 with the interposer layer 101 separately. The process of bonding the plurality of stacks 112 with the interposer layer 101 is simplified, the production efficiency of the semiconductor structure 100 is improved, and the unit per hour (UPH) of the semiconductor structure 100 can be increased.

It may be understood that the unit per hour (UPH) of the semiconductor structure 100 can be multiplied according to the number of the stacks 112 in the bonding block 110, which effectively solves the bottleneck in the UPH of back-end-of-line packaging and is conducive to reducing the production cost of the semiconductor structure 100.

Moreover, the size of the bonding block 110 is greater than that of the stack 112. Compared with the stacks 112 being bonded with the interposer layer 101 separately, the plurality of stacks 112 in the bonding block 110 as a whole are jointly bonded with the interposer layer 101, which may improve the convenience during the bonding of the stacks 112 and the interposer layer 101.

As such, the limitations of the size of the stack 112 on the UPH can be reduced, and the decrease in the size of the stack 112 will not have a significant impact on the UPH of the semiconductor structure 100 and is conducive to reducing the size of the stack 112 at the fabrication (FAB) end, such that a more flexible wafer design can be achieved during the fabrication of the stack 112.

That is, the connection portion 111 is provided to connect any two adjacent ones of the stacks 112, which can facilitate the miniaturization of the stack 112, increase the space utilization rate inside the semiconductor device 200, achieves more flexible packaging (PKG) design and more flexible space utilization and is conducive to achieving high integration.

Furthermore, the decrease in the size of the stack 112 can reduce the number of defects in the stack 112, and is conducive to increasing the yield of the stack 112, thereby increasing the yield of the semiconductor structure 100. Moreover, the area utilization rate of the stack wafer 113 (which comprises the plurality of stacks 112) can be also increased.

The above descriptions are merely example implementations of the present disclosure, and the protection scope of the present disclosure is not limited to thereto. Any variation or replacement that may be readily figured out by those skilled in the art within the technical scope disclosed by the present disclosure shall be encompassed within the protection scope of the present disclosure. Therefore, the scope of protection of the present disclosure should be defined by the scope of protection of the claims.

What is claimed is:

1. A semiconductor structure, comprising:
an interposer layer; and
a bonding block,
wherein the bonding block and the interposer layer are stacked together;
the bonding block comprises a connection portion and a plurality of stacks;
the connection portion connects any two adjacent ones of the plurality of stacks; and
any one of the plurality of stacks is bonded with the interposer layer.

2. The semiconductor structure of claim 1, wherein
the semiconductor structure comprises a plurality of bonding blocks;
the plurality of bonding blocks are stacked together; and
any two adjacent ones of the plurality of bonding blocks are bonded with each other.

3. The semiconductor structure of claim 2, wherein in any two adjacent ones of the plurality of bonding blocks, a plurality of stacks in one bonding block and a plurality of stacks in the other bonding block are bonded in a one-to-one correspondence.

4. The semiconductor structure of claim 1, wherein the connection portion comprises a connection medium and metal routings embedded in the connection medium.

5. The semiconductor structure of claim 1, wherein the stack comprises a logic chip and a memory chip that are stacked together, and the memory chip is bonded with the logic chip.

6. The semiconductor structure of claim 5, wherein the stack comprises a plurality of memory chips that are stacked together on a side of the logic chip, and any two adjacent ones of the plurality of memory chips are bonded with each other.

7. The semiconductor structure of claim 5, wherein the memory chip and the logic chip are bonded by at least one of adhesive bonding, anodic bonding, direct wafer bonding, metal bonding and hybrid bonding.

8. The semiconductor structure of claim 1, wherein the bonding block and the interposer layer are bonded by at least one of adhesive bonding, anodic bonding, direct wafer bonding, metal bonding and hybrid bonding.

9. The semiconductor structure of claim 1, wherein the plurality of stacks are arranged along at least one of a first direction and a second direction, the first direction intersects the second direction, and a plane where the first direction and the second direction are located is parallel to the interposer layer.

10. A fabrication method of a semiconductor structure, comprising:
forming a bonding block that comprises a connection portion and a plurality of stacks, wherein the connection portion connects any two adjacent ones of the plurality of stacks; and
bonding any one of the plurality of stacks with an interposer layer.

11. The fabrication method of the semiconductor structure of claim 10, wherein forming the bonding block comprises:
bonding a memory wafer and a logic wafer to form a stack wafer comprising m stacks that are connected together; and
cutting the stack wafer to form the bonding block comprising n stacks that are connected together, wherein m is greater than or equal to n, and both m and n are positive integers greater than 1.

12. The fabrication method of the semiconductor structure of claim 11, wherein m is greater than m, and after bonding the memory wafer and the logic wafer, the fabrication method comprises:
cutting the stack wafer to form a first stack and a second stack.

13. The fabrication method of the semiconductor structure of claim 11, wherein before bonding the memory wafer and the logic wafer, the fabrication method further comprises:
forming the memory wafer on a side of a first substrate, wherein the memory wafer comprises a plurality of memory chips, and any two adjacent ones of the plurality of memory chips are connected with each other;
forming the logic wafer on a side of a second substrate, wherein the logic wafer comprises a plurality of logic chips, and any two adjacent ones of the plurality of logic chips are connected with each other; and
bonding the memory wafer and the logic wafer comprises:
bonding the plurality of memory chips and the plurality of logic chips in a one-to-one correspondence.

14. A semiconductor device, comprising:
a circuit board; and
a semiconductor structure comprising:
an interposer layer; and
a bonding block,
wherein the bonding block and the interposer layer are stacked together;
the bonding block comprises a connection portion and a plurality of stacks;
the connection portion connects any two adjacent ones of the plurality of stacks; and
any one of the plurality of stacks is bonded with the interposer layer,
wherein the interposer layer of the semiconductor structure is coupled with the circuit board.

15. The semiconductor device of claim 14, further comprising a die that is bonded with the interposer layer.

16. The semiconductor device of claim 15, wherein the die comprises a graphics processing unit.

17. The semiconductor device of claim 14, wherein
the semiconductor structure comprises a plurality of bonding blocks;
the plurality of bonding blocks are stacked together; and
any two adjacent ones of the plurality of bonding blocks are bonded with each other.

18. The semiconductor device of claim 17, wherein in any two adjacent ones of the plurality of bonding blocks, a plurality of stacks in one bonding block and a plurality of stacks in the other bonding block are bonded in a one-to-one correspondence.

19. The semiconductor device of claim 14, wherein the connection portion comprises a connection medium and metal routings embedded in the connection medium.

20. The semiconductor device of claim 14, wherein the stack comprises a logic chip and a memory chip that are stacked together, and the memory chip is bonded with the logic chip.
